(19) United States
(12) Patent Application Publication
(10) Pub. No.: US 2025/0175026 A1
(43) Pub. Date: May 29, 2025

(54) ELECTRONIC DEVICE AND METHOD FOR BATTERY MANAGEMENT

(71) Applicant: Samsung Electronics Co., Ltd., Suwon-si (KR)

(72) Inventors: Chulhan KIM, Suwon-si (KR); Sungjin KIM, Suwon-si (KR); Kiwook HAN, Suwon-si (KR); Seungho LEE, Suwon-si (KR); Jaesung LEE, Suwon-si (KR); Hyekyung JEON, Suwon-si (KR)

(21) Appl. No.: 19/039,411

(22) Filed: Jan. 28, 2025

Related U.S. Application Data
(63) Continuation of application No. PCT/KR2023/010916, filed on Jul. 27, 2023.

(30) Foreign Application Priority Data
Aug. 2, 2022 (KR) 10-2022-0095958
Aug. 9, 2022 (KR) 10-2022-0099550

(51) Int. Cl. H02J 7/00

(52) U.S. Cl. CPC H02J 7/007182; H02J 7/00032

(57) ABSTRACT

The disclosure relates to an electronic device and method for battery management, wherein the electronic device may comprise: a memory storing instructions, a battery, a communication circuit, and at least one processor, comprising processing circuitry, electrically connected to the memory, the battery, and the communication circuit, wherein at least one processor, individually and/or collectively, is configured to execute the instructions and to: charge the battery with power applied from a first external electronic device based on the electronic device being connected to the first external electronic device through the communication circuit; identify a recharge entry time for the battery to reach a set recharge voltage after the battery is fully charged; identify a remaining battery capacity based on the recharge entry time; identify a life span level of the battery on the basis of the remaining battery capacity; and change the set full charge voltage and the set recharge voltage of the battery on the basis of life span level.

### CROSS-REFERENCE TO RELATED APPLICATIONS

This application is a continuation of International Application No. PCT/KR2023/010916 designating the United States, filed on Jul. 27, 2023, in the Korean Intellectual Property Receiving Office and claiming priority to Korean Patent Application Nos. 10-2022-0095958, filed on Aug. 2, 2022, and 10-2022-0099550, filed on Aug. 9, 2022, in the Korean Intellectual Property Office, the disclosures of each of which are incorporated by reference herein in their entireties.

### BACKGROUND

### Field

The disclosure relates to an electronic device and method for managing a battery.

### Description of Related Art

With digital technology advancing, electronic devices come in various types, such as smartphones, tablet personal computers (PCs), or personal digital assistants (PDAs). Electronic devices have been developed to be worn by users so as to enhance portability and user accessibility.

Electronic devices are providing more diversified services and additional functions. Steady development efforts are underway for electronic devices to meet various needs of users and to raise the usability of electronic devices.

Electronic devices are being developed in various forms to connect with various types of external electronic devices to provide functions or information, which are not able to be provided by the electronic devices. Further, the electronic device may allow external electronic devices to perform some functions of the electronic device or may receive various pieces of information through another network.

Conventional electronic devices lack continuous battery capacity measurement and are thus incapable of correction of battery capacity in long-term use, which may lead to rapid discharge and inefficient use of the battery as the actual battery capacity is smaller than the battery capacity set in the electronic device. Further, electronic devices (e.g., earbuds or earphones) that are supposed to be configured in plurality may experience an imbalance in battery capacity between the batteries thereof. To address the issues, the disclosure provides an electronic device and method for managing the battery to correct the battery capacity based on the recharge entry time.

### SUMMARY

According to an example embodiment of the disclosure, an electronic device may comprise: memory storing instructions, a battery, a communication circuit, and at least one processor, comprising processing circuitry. According to an example embodiment, at least one processor, individually or collectively, may be configured to execute the instructions and to cause the electronic device to: charge the battery with power applied from a first electronic device based on the electronic device being connected to the first external electronic device through the communication circuit; identify a recharge entry time at which the battery reaches a set recharge voltage after the battery is fully charged; identify a remaining battery capacity based on the recharge entry time; identify a long-cycling level of the battery based on the remaining battery capacity; and change the set full charge voltage and the set recharge voltage of the battery based on the long-cycling level.

According to an example embodiment, a method for operating an electronic device may comprise: charging a battery of the electronic device with power applied from a first electronic device based on the electronic device being connected to the first external electronic device through the communication circuit; measuring a recharge entry time at which the battery reaches a set recharge voltage after the battery is fully charged; identifying a remaining battery capacity based on the recharge entry time; identifying a long-cycling level of the battery based on the remaining battery capacity; and changing the set full charge voltage and the set recharge voltage of the battery based on the long-cycling level.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device 101 in a network environment 100 according to various embodiments;

FIGS. 2A, 2B, and 2C are diagrams illustrating example configurations of an electronic device and an external electronic device according to various embodiments;

FIG. 3 is a block diagram illustrating an example configuration of an electronic device according to various embodiments;

FIG. 4 is a graph related to battery charging in an electronic device according to various embodiments;

FIG. 5 is a graph related to battery charging in an electronic device according to various embodiments;

FIGS. 6A and 6B are tables related to battery charging of an electronic device according to various embodiments;

FIG. 7 is a flowchart illustrating an example method of operating an electronic device according to various embodiments; and

FIG. 8 is a flowchart illustrating an example method of operating an electronic device according to various embodiments.

In connection with the description of the drawings, the same or similar reference numerals may be used to denote the same or similar elements.

### DETAILED DESCRIPTION

Various embodiments of the present disclosure are now described in greater detail with reference to the accompanying drawings. As used herein, the term “user” may denote a human or another device using the electronic device.

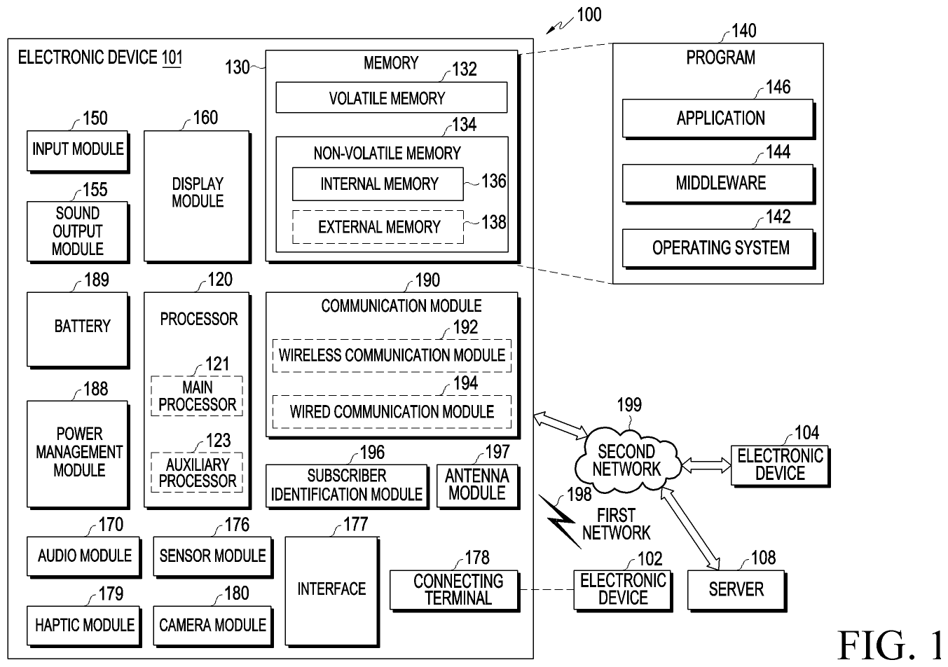

FIG. 1 is a block diagram illustrating an electronic device 101 in a network environment 100 according to various embodiments. Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

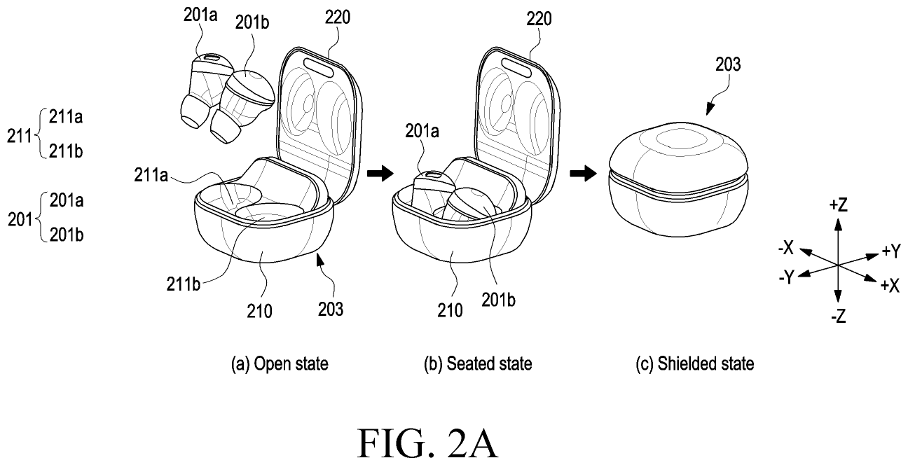

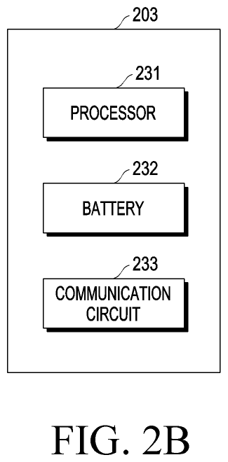

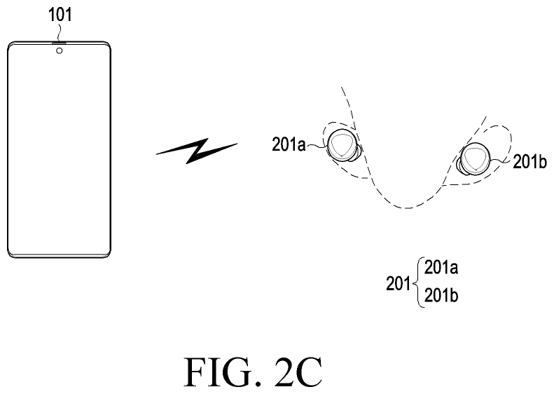

FIGS. 2A, 2B, and 2C are diagrams illustrating example configurations of an electronic device according to various embodiments.

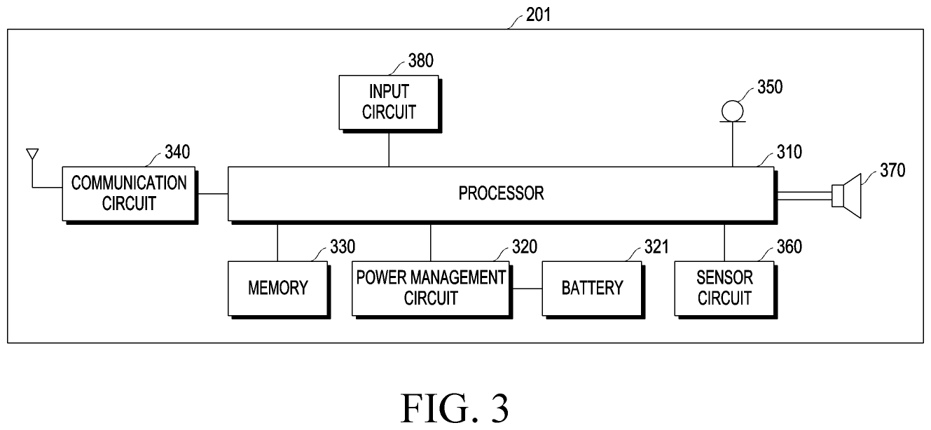

Referring to FIG. 2A, the electronic device 201 according to an embodiment may be connected to an external electronic device (e.g., the first external electronic device 203) using a wireless communication scheme, and may charge a battery (e.g., the battery 321 of FIG. 3) with power (e.g., voltage and/or current) applied from the first external electronic device 203. The electronic device 201 according to an embodiment is a wearable electronic device that may be worn on the body and includes components (e.g., a speaker and a microphone) related to at least one sound effect, and may be worn on a portion close to the user's ear, such as an in-ear earphone (or earset) and a hearing aid. According to an embodiment, the electronic device 201 may be stored in the first external electronic device 203, which is an accommodation device such as a cradle, for charging and/or storage.

According to an embodiment, the electronic device 201 may be worn on a part of the body, e.g., an ear or the head, and may be a wearable type electronic device (e.g., a pair of earphones (or earsets) and a hearing aid, a headset, or a speaker) including components (e.g., a speaker and a microphone) related to at least one sound effect. For example, the electronic device 201 may be one of a pair of first electronic device 201a and second electronic device 201b, respectively, that may be worn on both ears of the user. The first electronic device 201a and the second electronic device 201b may be implemented as a left earphone and a right earphone, respectively, that wirelessly output sound. For example, the electronic device 201 may be implemented as true wireless stereo (TWS)-based wireless earphones. The electronic device 201 according to an embodiment of the disclosure is not limited to the TWS scheme, and may be implemented as sound devices other than the TWS scheme. For convenience of description, the electronic device 201 according to an embodiment is described as the first electronic device 201a as an example, but the electronic device 201 may be the second electronic device 201b, and the second electronic device 201b may have the same components and technical features as those of the first electronic device 201a according to an embodiment.

Referring to FIG. 2A, the first external electronic device 203 according to an embodiment may be a cradle device configured in the form of a case capable of storing the electronic device 201. Based on the electronic device 201 being mounted in the internal accommodation space 211, the first external electronic device 203 may be wirelessly or wiredly connected to the electronic device 201 and may apply power for charging to the electronic device 201.

According to an embodiment, the first external electronic device 203 may be opened or closed, and the user may store the electronic device 201 (e.g., the first electronic device 201a and/or the second electronic device 201b) in a separate accommodation space 211. The accommodation space 211 may include a first accommodation space 211a and a second accommodation space 211b for accommodating the first electronic device 201a and the second electronic device 201b, respectively.

According to an embodiment, the first external electronic device 203 may include a first housing 210 and a second housing 220 disposed above the first housing 210 to shield at least a portion of the first housing 210. If the first housing 210 is shielded by the second housing 220, the electronic device 201 accommodated in the accommodation space 211 may be prevented or blocked from escaping off. According to an embodiment, the first external electronic device 203 may be electrically connected to the electronic device 201 to supply power to the electronic device 201 or to transmit or receive an electrical signal. According to an embodiment, various electronic components may be disposed inside the first housing 210 and/or the second housing 220 of the first external electronic device 203.

According to an embodiment, the first external electronic device 203 may have an open state a and a shield state c. The open state may refer to a state in which the second housing 220 does not shield the first housing 210 and the upper portion (+z-axis direction) of the first housing 210 is open. The shielded state may refer to a state in which the second housing 220 shields the first housing 210. Further, the seated state b may refer to a state in which the electronic device 201 is disposed in the first housing 210 (e.g., the accommodation space 211) in the open state. In the following description, the disclosure is described using the terms ‘open state’, ‘shielded state’, and ‘seated state’. In the disclosure, it will be understood that the first external electronic device 203 is not limited to a device related to the electronic device 201, but may be equally applied to all types of devices for charging.

Referring to FIG. 2B, the first external electronic device 203 according to an embodiment may include a processor (e.g., including processing circuitry) 231 (e.g., the processor 120 of FIG. 1), a battery 232 (e.g., the battery 189 of FIG. 1), and a communication circuit 233 (e.g., the communication module 190 of FIG. 1) to wirelessly charge the electronic device 201. According to an embodiment, the first external electronic device 203 may further include a power management circuit connected to the battery 232 to manage power, and the first external electronic device 203 may include a timer for measuring a full charge time and/or a recharge entry time when charging the electronic device 201. According to an embodiment, the timer may be included in the electronic device 201. The first external electronic device 203 may further include other components for interworking with the electronic device 201. As described above, the processor 231 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

Referring to FIG. 2C, an electronic device 201 (e.g., the electronic devices 201a or 201b) according to an embodiment may be connected to a second external electronic device 101 (e.g., the electronic device 101 of FIG. 1) using a wireless communication scheme to perform wireless communication.

According to an embodiment, in the electronic devices 201a and 201b, sound components (e.g., audio modules) and electronic components (e.g., processors) inside the electronic devices 201a and 201b may be disposed to enhance sound performance. According to an embodiment, the electronic devices 201a and 201b may function as an audio output interface (or a sound output module) that outputs a sound signal received from the second external electronic device 101 to the outside. The electronic devices 201a and 201b disclosed herein may function as an audio input interface (or input module) for receiving an audio signal corresponding to a sound obtained from the outside. According to an embodiment, each of the first electronic device 201a and the second electronic device 201b may convert data received from the second external electronic device 101 into sound and may output the converted sound (e.g., audio, music, ambient sound, notification sound, or phone sound) through the speaker. Each of the first electronic device 201a and the second electronic device 201b may obtain an external sound (e.g., the user's voice or ambient sound) through at least one microphone, and may transmit data corresponding to the obtained sound to the second external electronic device 101.

According to an embodiment, the electronic devices 201a and 201b may be wirelessly connected to the second external electronic device 101. For example, the electronic devices 201a and 201b may communicate with the second external electronic device 101 through a network (e.g., a short-range wireless communication network or a long-range wireless communication network). The network is not limited thereto, but may include a mobile or cellular communication network, a local area network (LAN) (e.g., Bluetooth communication), a wireless local area network (WLAN), a wide area network (WAN), the Internet, or a small area network (SAN). According to an embodiment, the electronic device 201 may be wiredly connected to the second external electronic device 101 using a cable (not shown).

For convenience of description, it is described that the electronic device 201 described with reference to the drawings of the disclosure is one of the first electronic device 201a and the second electronic device 201b, and the technical features and components of the first electronic device 201a may be equally or similarly applied to the second electronic device 201b. As described in an embodiment of the disclosure, the term “circuit” may be replaced with “module”.

FIG. 3 is a block diagram illustrating an example configuration of an electronic device according to various embodiments.

Referring to FIG. 3, an electronic device 201 (e.g., the first electronic device 201a or the second electronic device 201b) according to an embodiment may include a processor (e.g., including processing circuitry) 310 (e.g., the processor 120 of FIG. 1), a power management circuit 320 (e.g., the power management module 188 of FIG. 1), a battery 321 (e.g., the battery 189 of FIG. 1), memory 330 (e.g., the memory 130 of FIG. 1), a communication circuit 340 (e.g., the communication module 190 of FIG. 1), at least one microphone 350 (e.g., the input module 150 of FIG. 1), a sensor circuit 360 (e.g., the sensor circuit 360 of FIG. 1) including at least one sensor, a speaker 370 (e.g., the sound output module 155 of FIG. 1), and/or an input circuit 380 (e.g., the input module 150 of FIG. 1).

The processor 310 according to an embodiment may include various processing circuitry and be electrically or operatively connected to the power management circuit 320, the battery 321, the memory 330, the communication circuit 340, the at least one microphone 350, the sensor circuit 360 including at least one sensor, the speaker 370, and/or the input circuit 380, and may perform the overall control operation of the electronic device 201. The processor 310 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

According to an embodiment, the processor 310 may control the battery 321 that provides power to drive the electronic device 201. The processor 310 may manage charging and discharging of the battery 321 through the power management circuit 320. According to an embodiment, the processor 310 may include a voice processing circuit, and may control the voice processing circuit to process the audio data received from the second external electronic device 101 to output an audio signal (e.g., a sound signal).

According to an embodiment, the processor 310 may identify that the electronic device 201 is accommodated in the accommodation space 211 of the first external electronic device 203 and connected to the first external electronic device 203, and may charge the battery 321 with power applied from the battery 232 of the first external electronic device 203. The processor 310 may monitor the charging voltage level of the battery 321 to determine whether the battery 321 is fully charged, and may terminate charging if the battery 321 is fully charged. The processor 310 may transmit a control signal to terminate charging to the first external electronic device 203 through the communication circuit 340. After the battery 321 is fully charged, the processor 310 may monitor the recharge voltage to identify whether the battery 321 is recharged, and if the monitored battery voltage level reaches the recharge voltage value, the processor 310 may control to recharge the battery 321 from the start time of the recharge to the full charge time. The processor 310 may transmit a control signal to start recharging to the first external electronic device 203 through the communication circuit 340.

According to an embodiment, the power management circuit 320 may efficiently manage and optimize power use of the battery 321 in the electronic device 201. According to an embodiment, the power management circuit 320 may adjust power supplied to the processor 310 based on a signal provided according to a load to be processed by the processor 310, or may adjust power provided to each component (e.g., the memory, the communication module, the input module, and/or the sensor) in addition to the processor 310. According to an embodiment, the power management circuit 320 may include a battery charging module. According to an embodiment, the power management module 320 may receive power from the first external electronic device 203, which is an external power supply device, wiredly or wirelessly to charge the battery 321. According to an embodiment, the battery 321 may be charged with the power applied from the first external electronic device 203. In the battery 321, the battery voltage (capacity) reduces over time due to the natural discharge. Thus, if the voltage of the battery 321 reduces to the recharge voltage, it may be recharged up to the full charge voltage with the power applied from the first external electronic device 203.

According to an embodiment, the memory 330 may store various data and/or information used by at least one component (e.g., the power management circuit 320, the battery 321, the memory 330, the communication circuit 340, at least one microphone 350, the sensor circuit 360 including at least one sensor, the speaker 370, and/or the input circuit 380) of the electronic device 201. The data may include, e.g., software (e.g., a program) and input data or output data for a command related thereto. For example, the memory 330 may store instructions to perform the operation of the electronic device 201 (or the processor 310). According to an embodiment, the memory 330 may store information related to charging or recharging of the battery 321. The memory 330 may store a table (e.g., a first table) in which the battery capacity is set for each recharge entry time, and a table (e.g., a second table) for identifying the long-cycling level.

According to an embodiment, the electronic device 201 may provide a user interface related to a function of receiving audio data from the second external electronic device 101 or a function of transmitting audio data to the second external electronic device 101. For example, the user interface may include a light emitting means such as a light emitting diode (LED). For example, the light emitting means may be controlled to emit a color of light corresponding to charging or completion of charging. For example, if the electronic device 201 is communication-connected with the second external electronic device 101, the light emitting means may be controlled to emit a specific color of light.

At least one microphone 350 according to an embodiment may obtain a sound signal in an on (e.g., active or operation) state. When the electronic device 201 includes a plurality of microphones, and the electronic device 201 is inserted into an ear, at least one (e.g., inner mic) of the plurality of microphones may be disposed at the position closest to the inside of the ear, and at least one other microphone may be disposed outside the ear when the electronic device 201 is worn in the user's ear. At least one microphone 350 may be turned on (e.g., activated or operated) or off (e.g., deactivated or not operated) under the control of the processor 310. In FIG. 3, the electronic device 201 is illustrated to include at least one microphone 350, but the technical spirit of the disclosure may not be limited thereto. For example, the number of microphones may be two or more than three as the plurality of microphones.

The sensor circuit 360 according to an embodiment may include at least one sensor that may measure or detect (e.g., determine or identify) an amount of change (e.g., vibration, movement, and/or sound) in the surrounding environment. According to an embodiment, the sensor circuit 360 may include a voice pick up (VPU) sensor. For example, the VPU sensor may include a plurality of axial acceleration sensors (e.g., a three-axial acceleration sensor, a six-axial acceleration sensor, or other multi-axial acceleration sensors), and may detect a signal (e.g., a vibration signal, a movement signal, or a sound signal) transmitted through at least a portion of the user's body for each axis. For example, when a voice is uttered by the user, the vibration of the vocal cord of the user may be detected by the plurality of axial acceleration sensors to be obtained as a signal of at least some of a plurality of sounds related to the voice signal. According to an embodiment, the plurality of axial acceleration sensors may be controlled by the processor 310 to selectively activate or operate (e.g., turn on) at least some of the plurality of axes. The technical spirit of the disclosure may not be limited thereto and may further include other sensors related to audio signal processing.

According to an embodiment, the speaker 370 may output an audio signal (e.g., sound signal) under the control of the processor 310.

The input circuit 380 according to an embodiment may be configured to generate various input signals necessary for operation (or operation control) of the electronic device 201. For example, the input circuit 380 may include a touch pad, a touch panel, or a button. The touch pad may recognize touch inputs in at least one of capacitive, resistive, infrared, or ultrasonic methods. If a capacitive touch pad is provided, physical contact or proximity recognition may be possible. The touch pad may further include a tactile layer. The touch pad including the tactile layer may provide a tactile response to the user. The button may include, e.g., a physical button and/or an optical key. For example, the input circuit 380 may generate an input signal according to the user input and transmit the input signal to the processor 310. For example, the user input may be an input associated with a call state entry, call state termination, volume control, and/or mute function.

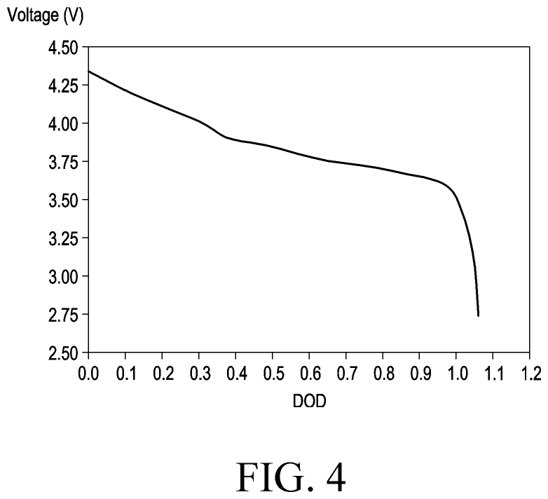

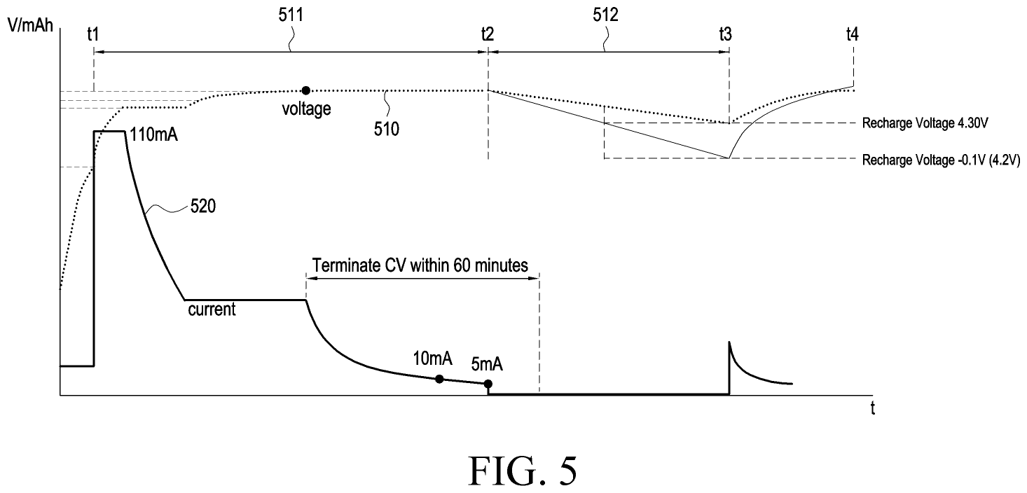

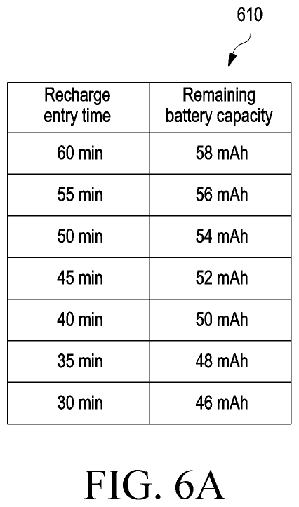

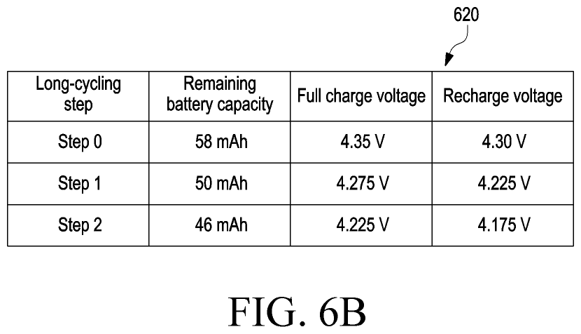

FIGS. 4 and 5 are graphs related to battery charging in an electronic device according to various embodiments. FIGS. 6A and 6B are tables related to battery charging of an electronic device according to various embodiments.

According to an embodiment, as shown in the graph of FIG. 4, the battery capacity characteristic of the battery 321 of the electronic device 201 may decrease over time. For example, if the battery capacity characteristic decreases (e.g., lower than 4.35 V) from the full charge voltage (e.g., 4.35 V) and the recharge voltage (e.g., 4.30 V) set in the battery 321 of the electronic device 201, the time at which the voltage with the decreased battery capacity characteristic reaches the set recharge voltage (e.g., 4.30 V) may be shorter than the set full charge voltage (e.g., 4.35 V).

Referring to FIG. 5, according to an embodiment, the processor 310 may monitor a battery voltage (e.g., a first graph 510) for charging and recharging the battery 321 at a charge-discharge cycle (time period of t1 to t3). Here, the charge-discharge cycle may be a time period including a first time period (e.g., a charge period) 511 from the charge start time t1 of the battery 321 to the full charge time t2 of the full charge voltage (e.g., 4.35V) and a second time period (e.g., a discharge period) 512 from the full charge time t2 to the recharge start time t3 of the recharge voltage (e.g., 4.30V). Here, the second graph 520 of FIG. 5 may represent a graph (e.g., a constant current (CC)-constant voltage (CV)) indicating the battery current value according to battery charge and recharge operations during a charge-discharge period (t1 to t3 time period). Here, the t1-t2 period illustrated in FIG. 5 may indicate a battery charge period of 0% to 100%, the t2-t3 period may indicate a battery discharge period (e.g., natural discharge) after full charge, and the t3-t4 period may indicate a recharge operation period. For example, if the full charge voltage and the recharge voltage are changed again after performing the operation for changing the full charge voltage and the recharge voltage according to an embodiment, as illustrated in FIG. 5, the recharge voltage may be changed to be low as a next designated level of the recharge voltage (−0.1 V (e.g., 4.2 V)). According to an embodiment, when the monitored battery voltage is the set recharge voltage (e.g., 4.30V), the processor 310 may identify that it is at the recharge start time t3 and measure the time when the battery 321 reaches the recharge voltage from the full charge time t2 as the recharge entry time (e.g., the second time period 512). The processor 310 may repeatedly perform the operation (e.g., the operation in the t2-t3 time period) for measuring the recharge entry time for a designated time (e.g., 5 to 6 hours) using the timer, and may repeatedly measure the recharge entry time through the repeatedly performed recharge operation. The processor 310 may obtain an average time of the recharge entry time (e.g., the second time period 512) measured for the designated time, and identify the average time as the recharge entry time for identifying the remaining battery capacity.

According to an embodiment, the processor 310 may identify the battery capacity based on the identified recharge entry time (e.g., the average time of the recharge entry time). The processor 310 may identify the battery capacity corresponding to the identified recharge entry time using a table (e.g., the first table 610 of FIG. 6A) in which the battery capacity for each recharge entry time is set, stored in the memory 330. The first table 610 may be a table preset (e.g., specified) through a product experiment, and may be stored in the memory 330 when the electronic device 201 is purchased. If the first table 610 is not stored in the memory 330, the processor 310 may receive it from an external electronic device (e.g., the second external electronic device 101 or the server of FIGS. 1 and 2) through wireless communication. According to an embodiment, if the battery 321 of the electronic device 201 is replaced, the first table 610 may be updated or reset based on the replaced battery 321.

According to an embodiment, the processor 310 may identify the long-cycling level of the battery based on the remaining battery capacity, and may change the full charge voltage and the recharge voltage of the battery 321 based on the long-cycling level. The processor 310 may identify the long-cycling level corresponding to the battery capacity using the second table (e.g., the second table 620 of FIG. 6B) stored in the memory 330. The processor 310 may identify a full charge voltage value and a recharge voltage value corresponding to the long-cycling level, and change the full charge voltage and the recharge voltage of the battery 321 to the identified full charge voltage value and recharge voltage value. The processor 310 may control to perform the charge and recharge operations of the battery 321 during the charge-discharge period (t1 to t3 time period) based on the changed full charge voltage value and recharge voltage value.

Referring to FIGS. 6A and 6B, according to an embodiment, the processor 310 may identify the remaining battery capacity set in the first table 610 as, e.g., 50 mAh when the identified recharge entry time is measured as 40 minutes after being measured as a time exceeding, e.g., 40 minutes (min). The processor 310 may identify the long-cycling level corresponding to the remaining battery capacity of the second table 620 indicating the identified 50 mAh as, e.g., level 1, and change the long-cycling level from level 0 to level 1. The processor 310 may identify a full charge voltage value (e.g., 4.275V) and a recharge voltage value (4.225V) set corresponding to level 1 in the second table 620, and change the full charge voltage and the recharge voltage of the battery 321 to the identified full charge voltage value (e.g., 4.275V) and recharge voltage value (4.225V), respectively. Here, the remaining battery capacity values set respectively corresponding to the long-cycling levels in the second table may be entry reference values at which the long-cycling level is changed. If the battery capacity is identified as 58 mAh to 51 mAh, the processor 310 may identify the long-cycling level as level 0, if the battery capacity is identified as 50 mAh to 47 mAh, the processor 310 may identify the long-cycling level as level 1, and if the battery capacity is identified as 46 mAh or less, the processor 310 may identify the long-cycling level as level 2.

According to an embodiment, the processor 310 may control the communication circuit 340 to transmit a control signal to the second electronic device 201b to change the full charge voltage and the recharge voltage of the battery 330 of the second electronic device 201b to the changed full charge voltage value and the changed recharge voltage value in the first electronic device 201a.

According to an embodiment, the processor 310 may control the control circuit 340 to transmit information related to battery charging of the first electronic device 201a to the second electronic device 201b, and to receive the information related to battery charging of the second electronic device 201b from the second electronic device 201b. Here, the information related to battery charging of the first electronic device 201a and the second electronic device 201b may include at least one of the remaining battery capacity value, the long-cycling level, the changed full charge voltage value, and/or the changed recharge voltage value.

According to an embodiment, when it is described that the electronic device 201 is the first electronic device 201a, the processor 310 may compare the long-cycling level of the first electronic device 201a with the long-cycling level of the second electronic device 201b, based on the information related to battery charging received from the second electronic device 201b. The processor 310 may identify the higher long-cycling level of the long-cycling level of the first electronic device 201a and the long-cycling level of the second electronic device 201b as the long-cycling level for changing the full charge voltage and the recharge voltage. The processor 310 may match the long-cycling levels of the first electronic device 201a and the second electronic device 201b to the identified long-cycling level. For example, if the long-cycling level of the first electronic device 201a is high, the processor 310 may control the communication circuit 340 to transmit, to the second electronic device 201b, information related to battery charging including the long-cycling level, the changed full charge voltage value, and recharge voltage value identified in the first electronic device 201a. For example, if the long-cycling level of the second electronic device 201a is high, the processor 310 may change the long-cycling level, the full charge voltage, and the recharge voltage of the battery 321 based on the battery charging-related information (e.g., including the long-cycling level, the full charge voltage value, and the recharge voltage value) received from the second electronic device 201b. According to an embodiment, the first electronic device 201a and the second electronic device 201b may transmit and receive information about their respective long-cycling levels through the communication circuit 340, and may set the full charge voltage and the recharge voltage based on the long-cycling level of the device having the higher long-cycling level.

According to an embodiment, if any one of the first electronic device 201a and the second electronic device 201b is replaced with a new product or has the battery replaced with a new battery, the processor 310 may perform an operation for matching the long-cycling level of the first electronic device 201a and the long-cycling level of the second electronic device 201b. When the processor 310 is communicatively connected to the second external electronic device 101, the processor 310 may control the communication circuit 340 to transmit, to the second external electronic device 101, information related to battery charging (e.g., including the long-cycling level, the full charge voltage value, and/or the recharge voltage value) identified through the operation (e.g., the operation in the time period of t2-t3 in the drawings) for measuring the recharge entry time of the first electronic device 201a. For example, if the second housing 220 of the first external electronic device 203 is opened or the electronic device 201 (e.g., the first electronic device 201a) is not accommodated in the accommodation space 211, the electronic device 201 (e.g., the first electronic device 201a) may be communicatively connected to the second external electronic device 101 through wireless communication (e.g., Bluetooth communication). The electronic device 201 (e.g., the first electronic device 201a) may be paired with the paired second electronic device 201b to be communicatively connected with the second external electronic device 101.

According to an embodiment, the second external electronic device 101 may identify whether the long-cycling level is changed based on the long-cycling level, the full charge voltage value, and/or the recharge voltage value included in the battery charging-related information received from the first electronic device 201a. As the second electronic device 201b paired with the first electronic device 201 also performs a long-cycling operation of the battery like the first electronic device 201b, the second external electronic device 101 may receive information related to battery charging from the second electronic device 201b. The second external electronic device 101 may compare the long-cycling level of the first electronic device 201a and the long-cycling level of the second electronic device 201b and, when the long-cycling levels differ from each other, transmit a control signal including the long-cycling level information to the first electronic device 201a and/or the second electronic device 201b to match the long-cycling levels. Here, the long-cycling level information may include the long-cycling level of the first electronic device 201a and/or the long-cycling level of the second electronic device 201b, or the long-cycling level having the greater value of the two long-cycling levels. The disclosure is not limited thereto, and the second external electronic device 101 may periodically transmit the long-cycling level of the first electronic device 201a to the second electronic device 201b and may periodically transmit the long-cycling level of the second electronic device 201b to the first electronic device 201a while being connected to the first electronic device 201a and the second electronic device 201b.

According to an embodiment, when the first electronic device 201a and the second electronic device 201b are accommodated in the accommodation space 211 of the first external electronic device 203, each of the first electronic device 201a and the second electronic device 201b may perform communication for information transmission/reception with the first external electronic device 203 through power line communication (PLC). The first external electronic device 203 may bypass communication between two of the first electronic device 201a and the second electronic device 201b, may receive information related to battery charging from the first electronic device 201a and/or the second electronic device 201b, and may transmit the information related to battery charging to the first electronic device 201a and/or the second electronic device 201b. The first external electronic device 203 may transmit a control signal including the long-cycling level information to the first electronic device 201a and/or the second electronic device 201b to match the long-cycling levels.

According to an embodiment, the processor 310 may execute battery long-life operations implemented by a software program (e.g., an application). The processor 310 may execute instructions stored in the memory 330 to implement the software program for long-lived battery operations, and may control hardware (e.g., the power management circuit 320, the battery 321, the communication circuit 340, the sensor circuit 360, the speaker 370, and/or the input circuit 380 of FIG. 3) associated with the function of the software program.

According to an embodiment, based on the communication connection with the second external electronic device 101, the processor 310 may periodically receive the long-cycling level of the second electronic device 201b from the second external electronic device 101 or, when it differs from the long-cycling level of the second electronic device 201b, may receive long-cycling level information (e.g., including the long-cycling level of the second electronic device 201b or the long-cycling level determined to be the higher value) from the second external electronic device 101.

According to an embodiment, the processor 310 may identify the long-cycling level having the higher value based on the long-cycling level information received from the second external electronic device 101 or the long-cycling level of the second electronic device 201b periodically received and change the battery full charge voltage or recharge voltage to be matched to the long-cycling level having the higher value or request the second external electronic device 101 to match the long-cycling levels. Here, the higher long-cycling level may reduce the battery capacity due to aging and may refer, for example, to the battery lifespan shortening. For example, if any one of the first electronic device 201a and the second electronic device 201b is replaced with a new one or has its battery replaced with a new battery, or reset, the second external electronic device 101 may perform connection pairing with the first electronic device 201a and the second electronic device 201b, and may perform an operation for matching the long-cycling levels. For example, since the electronic device (e.g., the second electronic device 201b) replaced or having its battery replaced with a new battery has the battery capacity (e.g., remaining battery capacity) characteristic identified as the capacity value set when shipped out although its long-cycling level is downgraded to the long-cycling level of the electronic device (e.g., the first electronic device 201a), the second external electronic device 101 may identify that the electronic device is a newly replaced one or has its battery replaced with a new battery. If the battery capacity characteristic identified based on the battery charging-related information about another electronic device (e.g., the second electronic device 201b) received from the second external electronic device 101 is identified as the capacity value set at the time of being manufactured or shipped out, the electronic device 201 (e.g., the first electronic device 201a) may identify that the other electronic device is a newly replaced one or has its battery replaced with a new battery. For example, when the remaining battery capacity value of the other electronic device (e.g., the first electronic device 201a) has no change as compared with the remaining capacity value identified at the time of being manufactured or shipped out or is increased over the previously identified remaining battery capacity, the electronic device 201a may identify that the other electronic device is a newly replaced one or has its battery replaced with a new battery.

According to an embodiment, when connected to the second external electronic device 101, the first electronic device 201a and the second electronic device 201b may transmit product information (e.g., the serial number, battery characteristic information, or pairing-related information) to the second external electronic device 101. When the serial numbers included in the product information are different from each other, the second external electronic device 101 or the first electronic device 201a and the second electronic device 201b may not perform the operation for matching the long-cycling levels. The disclosure is not limited thereto, and the second external electronic device 101 or the first electronic device 201a and the second electronic device 201b may perform the operation for matching the long-cycling levels regardless of the product serial number, or may perform the operation for matching the long-cycling levels based on the same identification number generated in association with different product serial numbers or a virtual same serial number.

According to an embodiment, the electronic device 201 may further include various modules (or circuits) according to the type in which it is provided. There are many variations according to the convergence trend of digital devices, so it is not possible to list them all, but components equivalent to the above-mentioned components may be further included in the electronic device 201. Further, it is apparent that in the electronic device 201 according to an embodiment, specific components may be excluded from the above components or replaced with other components according to the form in which it is provided. This will be easily understood by those of ordinary skill in the art.

According to an example embodiment, an electronic device (e.g., The electronic device 201 of FIGS. 2A, 2C, and 3) may comprise: memory storing instructions (e.g., the battery 321 of FIG. 3), a battery (e.g., the battery 321 of FIG. 3), a communication circuit (e.g., the communication circuit 340 of FIG. 3), and at least one processor, comprising processing circuitry (e.g., the processor 310 of FIG. 3), electrically connected to the memory, the battery, and the communication circuit. According to an example embodiment, at least one processor, individually or collectively, may be configured to execute the instruction and to cause the electronic device to: charge the battery with power applied from a first electronic device (e.g., the first external electronic device 203 of FIGS. 2A and 2B) based on the electronic device being connected to the first external electronic device through the communication circuit. According to an embodiment, the instructions may, when executed by the at least one processor individually or collectively, cause the electronic device to identify a recharge entry time at which the battery reaches a set recharge voltage after the battery is fully charged; identify a remaining battery capacity based on the recharge entry time; identify a long-cycling level of the battery based on the remaining battery capacity; and change the set full charge voltage and the set recharge voltage of the battery based on the long-cycling level.

According to an example embodiment, at least one processor, individually or collectively, may be configured to cause the electronic device to: repeatedly identify the recharge entry time at which the battery reaches the set recharge voltage after the battery is fully charged, at a charge-discharge cycle during a designated time, obtain an average time of recharge entry times identified during the designated time, and identify the average time as the recharge entry time for identifying the remaining battery capacity.

According to an example embodiment, at least one processor, individually or collectively, may be configured to cause the electronic device to: change the full charge voltage and the recharge voltage of the battery to a full charge voltage value and a recharge voltage value stored in the memory, corresponding to the long-cycling level.

According to an example embodiment, at least one processor, individually or collectively, may be configured to cause the electronic device to: provide information related to battery charging of the electronic device to another electronic device formed as a pair with the electronic device through the second external electronic device (e.g., the electronic device 101 of FIG. 1 or the second external electronic device 101 of FIG. 2C) to set the same long-cycling level as the other electronic device; and wherein the information related to battery charging of the electronic device may include the remaining battery capacity, the long-cycling level, the changed full charge voltage value, and the changed recharge voltage value.

According to an example embodiment, at least one processor, individually or collectively, may be configured to cause the electronic device to: receive information related to battery charging of another electronic device paired with the electronic device from the second external electronic device, and change the full charge voltage and the recharge voltage based on the information related to battery charging of the other electronic device. According to an example embodiment, the information related to battery charging of the other electronic device may include a remaining battery capacity, a long-cycling level, a full charge voltage value, and a recharge voltage value.

According to an example embodiment, at least one processor, individually or collectively, may be configured to cause the electronic device to: identify whether to replace the other device and whether to replace a battery of the other electronic device in response to identifying that the long-cycling level of the other device is changed to a high level like the long-cycling level of the electronic device without a change in the remaining battery capacity of the other electronic device.

According to an example embodiment, at least one processor, individually or collectively, may be configured to cause the electronic device to: identify a long-cycling level having a high value based on the long-cycling level of the electronic device being different from the long-cycling level of the other electronic device, set the long-cycling level of the electronic device to the long-cycling level having the high value, change the full charge voltage and the recharge voltage to a full charge voltage value and a recharge voltage value stored in the memory, corresponding to the long-cycling level having the high value, and provide the other electronic device with information related to battery charging including the long-cycling level having the high value to set the long-cycling level of the electronic device and the long-cycling level of the other electronic device to be the same.

According to an example embodiment, the long-cycling level may be set to a level that increases as the remaining battery capacity decreases, and each of the set full charge voltage and the set recharge voltage may be set to a value that decreases as the long-cycling level increases.

According to an example embodiment, at least one processor, individually or collectively, may be configured to cause the electronic device to: charge the battery with the voltage applied from the first external electronic device based on the electronic device being accommodated in an accommodation space inside a first housing of the first external electronic device, and a second housing of the first external electronic device being in a closed state, and refrain from performing wireless communication with a second external electronic device when charging the battery by the first external electronic device.

According to an example embodiment, at least one processor, individually or collectively, may be configured to cause the electronic device to: control the control circuit to receive product information about another electronic device connected with the second external electronic device using the wireless communication scheme and paired with the electronic device from the second external electronic device, and based on the received product information being identical to product information about the electronic device, control the communication circuit to transmit battery charging-related information about the electronic device to change the set full charge voltage and the set recharge voltage like the electronic device.

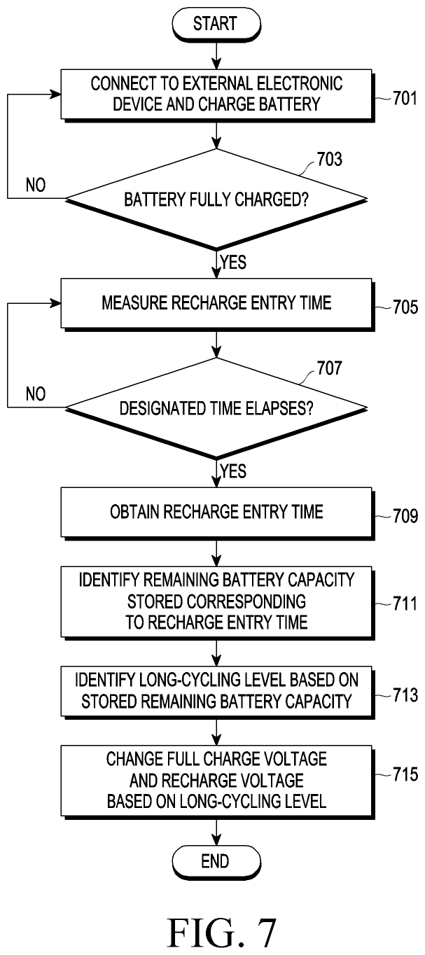

FIG. 7 is a flowchart illustrating an example method of operating an electronic device according to various embodiments. For convenience of description, the electronic device (e.g., the electronic device 201: 201a of FIGS. 2A, 2B, 2C, and 3) described in FIG. 7 is an electronic device for outputting a sound (e.g., an audio signal), and a first electronic device (e.g., the first electronic device 201a of FIGS. 2A and 2C), which is one of paired electronic devices (e.g., the first electronic device 201a and the second electronic device 201b), is described as an example. The disclosure is not limited thereto, and operations by the first electronic device 201a described in FIG. 7 may be performed in the same manner in the second electronic device 201b.

Referring to FIG. 7, in operation 701, the electronic device (e.g., the first electronic device 201a of FIGS. 2A and 2C) according to an embodiment may charge a battery (e.g., the battery 321 of FIG. 3) of the electronic device with power applied from the first external electronic device, based on being electrically connected to the first external electronic device (e.g., the first external electronic device 203 of FIGS. 2A and 2B). When the second housing 220 of the first external device is in the shielded state (e.g., (c) of FIG. 2A) after being accommodated in the accommodation space (e.g., the accommodation spaces 211a and 211b of FIG. 2A) of the first housing (e.g., the first housing 210 of FIG. 2A), the battery of the electronic device may be charged (e.g., wirelessly charged) with power applied from the battery 232 of the first external device. Similarly, the other electronic device (e.g., the second electronic device 201b of FIGS. 2A and 2C) paired with the electronic device may charge (e.g., wirelessly charge) the battery after being accommodated in the accommodation space of the first housing (e.g., the first housing 210 of FIG. 2A) of the first external electronic device. According to an embodiment, the electronic device may charge the battery even when the first external electronic device is in the open state (e.g., (a) of FIG. 2A) rather than the shielded state, but the battery charging efficiency may be decreased compared to the battery charging in the shielded state. According to an embodiment, when the electronic device charges the battery in the open state, charging the battery in a state in which communication with the second external electronic device is not connected may increase battery charging efficiency.

In operation 703, the electronic device according to an embodiment may identify whether the battery is fully charged. As a result, if the battery charging is in the fully charged state (yes in operation 703), the electronic device may perform operation 705, and if the battery charging is not in the fully charged state (no in operation 703), the electronic device may perform operation 701 for keeping charging the battery.

In operation 705, the electronic device according to an embodiment may monitor the battery voltage due to the natural discharge of the battery after the battery is fully charged, and may measure (e.g., detect, determine or identify) the recharge entry time 512 from the time when the battery is fully charged until the recharge voltage is reached (e.g., the time period t2-t3 of FIG. 5). The electronic device may repeatedly measure the recharge entry time 512 by repeatedly performing an operation (e.g., an operation in the t2-t3 time period of FIG. 5) for measuring the recharge entry time for a designated time (e.g., 5 to 6 hours) using the timer. Here, the timer may be included in the electronic device or configured to be included in the first external electronic device 203. If the timer is configured in the first external electronic device 203, the recharge entry time may be obtained from the first external electronic device 203. However, the disclosure is not limited thereto, and the electronic device according to an embodiment may repeatedly measure the recharge entry time a designated number of times by performing the operation (e.g., the operation in the t2-t3 time period of FIG. 5) for measuring the recharge entry time the designated number of times (e.g., 5-10 times).

In operation 707, the electronic device according to an embodiment may identify whether a designated time elapses. As a result of the identification, if the designated time elapses (yes in operation 707), the electronic device may perform operation 709, and if the designated time does not elapse (no in operation 707), the electronic device may perform operation 705 again.

In operation 709, the electronic device according to an embodiment may calculate an average value of the recharge entry time values measured for the designated time, and may obtain the average time corresponding to the average value as the recharge entry time for identifying the remaining battery capacity. According to an embodiment, the electronic device may omit operations 707 and 709 depending on the context for measuring the recharge entry time when performing the long-cycling operation to change the battery full charge voltage and the recharge voltage. For example, the electronic device may temporarily measure the recharge entry time values at the charge-discharge cycle, and may measure the recharge entry time by selecting a time value or the shortest time value measured in duplicate among the measured recharge entry time values. For example, the electronic device may measure the recharge entry time once.

In operation 711, the electronic device according to an embodiment may identify the remaining battery capacity based on the recharge entry time. The electronic device may identify the remaining battery capacity stored corresponding to the recharge entry time measured using the first table (e.g., the first table 610 of FIG. 6A) stored in the memory (e.g., the memory 330 of FIG. 3). Here, the recharge entry time may be an average recharge entry time which is the average value of the recharge entry time values measured repeatedly for a designated time or a designated number of times.

In operation 713, the electronic device according to an embodiment may identify the long-cycling level of the battery based on the identified remaining battery capacity. The electronic device may identify the long-cycling level stored corresponding to the remaining battery capacity identified using the second table (e.g., the second table 620 of FIG. 6B) stored in the memory (e.g., the memory 330 of FIG. 3).

In operation 715, the electronic device according to an embodiment may change the full charge voltage and the recharge voltage of the battery based on the identified long-cycling level. The electronic device may identify the full charge voltage value and the recharge voltage value stored corresponding to the long-cycling level identified using the second table (e.g., the second table 620 of FIG. 6B) stored in the memory (e.g., the memory 330 of FIG. 3) and change the full charge voltage and recharge voltage of the battery to the identified full charge voltage value and the recharge voltage value.

According to an embodiment, the electronic device may provide information related to battery charging of the electronic device to another electronic device (e.g., the second electronic device) paired with the electronic device through the second external electronic device (e.g., the second external electronic device 101 of FIGS. 1 and 2C) to set the same long-cycling level as the other electronic device. Here, the information related to battery charging of the electronic device may include the remaining battery capacity, the long-cycling level, the changed full charge voltage value, and the changed recharge voltage value. According to an embodiment, when the electronic device is accommodated in the first external electronic device (e.g., the first external electronic device 203 of FIGS. 2A and 2C), the electronic device may provide information related to battery charging of the electronic device to the other electronic device through the first external electronic device to set the same long-cycling level as the other electronic device (e.g., the second electronic device) paired therewith.

According to an embodiment, in operation 715, the electronic device may receive information related to battery charging of another electronic device paired with the electronic device from the second external electronic device, and change the full charge voltage and the recharge voltage based on the information related to battery charging of the other electronic device. Here, the information related to battery charging of the other electronic device may include the remaining battery capacity, the long-cycling level, the full charge voltage value, and the recharge voltage value.

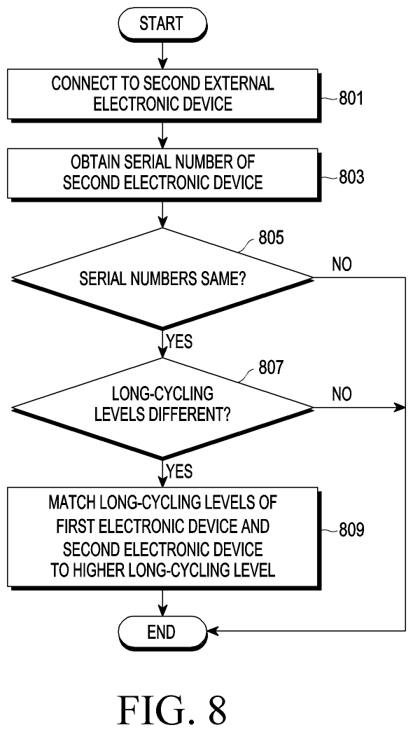

FIG. 8 is a flowchart illustrating an example method of operating an electronic device according to various embodiments. For convenience of description, the electronic device (e.g., the electronic device 201: 201a of FIGS. 2A, 2B, 2C, and 3) described in FIG. 7 is an electronic device for outputting a sound (e.g., an audio signal), and a first electronic device (e.g., the first electronic device 201a of FIGS. 2A and 2C), which is one of paired electronic devices (e.g., the first electronic device 201a and the second electronic device 201b), is described as an example. The disclosure is not limited thereto, and operations by the first electronic device 201a described in FIG. 7 may be performed in the same manner in the second electronic device 201b.

Referring to FIG. 8, in operation 801, the electronic device (e.g., the first electronic device 201a of FIGS. 2A and 2C) according to an embodiment may communicatively connect with the second external electronic device (e.g., the electronic device 101 of FIG. 1 and the second external electronic device 101 of FIG. 2C). The electronic device may be connected to the second external electronic device through a wireless communication scheme (e.g., Bluetooth) to perform wireless communication. When the electronic device is connected to the second external electronic device, the electronic device may be in a state of performing wireless communication with the second external electronic device without being accommodated in the first external electronic device (e.g., the first external electronic device 203 of FIGS. 2A and 2B) or with the second housing (e.g., the second housing 220 of FIG. 2A) of the first external electronic device open. According to an embodiment, the electronic device may transmit, to the second external electronic device, information related to battery charging obtained through the long-cycling operation method as shown in FIG. 7. The information related to battery charging of the electronic device may be transmitted to the second external electronic device automatically when connected to the second external electronic device, transmitted to the second external electronic device periodically when connected to the second external electronic device, or transmitted at the request of the second external electronic device. The information related to battery charging of the electronic device may include the remaining battery capacity, the long-cycling level, the full charge voltage value, and the recharge voltage value. According to an embodiment, the electronic device may receive, from the second external electronic device, information related to battery charging of the other electronic device obtained through the long-cycling operation method as shown in FIG. 7.

In operation 803, the electronic device according to an embodiment may obtain product information including the serial number of the other electronic device (e.g., the second electronic device) from the second external electronic device.

In operation 805, the electronic device according to an embodiment may identify whether the serial number of the other electronic device is the same as the serial number of the electronic device. As a result of the identification, if the serial numbers are the same (yes in operation 805), the electronic device may perform operation 807 and, if not the same (no in operation 805), terminate the operation. According to an embodiment, the electronic device may omit operations 803 and 805. For example, operations 803 and 805 may be performed by the second external electronic device in which case the electronic device may receive a control signal for requesting to match the long-cycling levels when the serial numbers are the same from the second external electronic device and perform operations 807 and 809. For example, the electronic device may perform the operations for matching the long-cycling level as in operations 807 and 809 regardless of the serial numbers, without performing operations 803 and 805.

In operation 807, the electronic device according to an embodiment may identify the long-cycling level of the other electronic device based on the information related to battery charging of the other electronic device and identify whether the long-cycling level of the electronic device differs from the long-cycling level of the other electronic device. As a result of the identification, if the long-cycling levels differ (yes in operation 807) from each other, the electronic device may perform operation 809 and, if the same (no in operation 807), terminate the operation.

In operation 809, the electronic device according to an embodiment may identify the long-cycling level having a higher value of the long-cycling levels of the electronic device and the other electronic device and match the long-cycling levels of the electronic device and the other electronic device to the long-cycling level having the higher value.

According to an embodiment, the electronic device and the other electronic device each may identically set or change the full charge voltage and recharge voltage of the battery to the full charge voltage value and the recharge voltage value stored corresponding to the matched long-cycling level.

According to an embodiment, the electronic device may identify whether to replace the other device and whether to replace a battery of the other electronic device in response to identifying that the long-cycling level of the other device is changed to a high level like the long-cycling level of the electronic device without a change in the remaining battery capacity of the other electronic device.

According to an example embodiment, a method of operating in an electronic device (e.g., the electronic device 201 of FIGS. 2A, 2C, and 3) may comprise: charging a battery (e.g., the battery 321 of FIG. 3) of the electronic device with power applied from a first external electronic device (e.g., the first external electronic device 203 of FIGS. 2A and 2B) based on being connected to the first external electronic device; identifying a recharge entry time at which the battery reaches a set recharge voltage after the battery is fully charged; identifying a remaining battery capacity based on the recharge entry time; identifying a long-cycling level based on the remaining battery capacity; and changing the set full charge voltage and the set recharge voltage of the battery based on the long-cycling level.

According to an example embodiment, identifying the recharge entry time may include repeatedly identifying the recharge entry time at which the battery reaches the set recharge voltage after the battery is fully charged, at a charge-discharge cycle during a designated time, obtaining an average time of recharge entry times identified during the designated time, and identifying the average time as the recharge entry time for identifying the remaining battery capacity.

According to an example embodiment, changing the set full charge voltage and the set recharge voltage of the battery may include changing the set full charge voltage and the set recharge voltage of the battery to a full charge voltage value and a recharge voltage value stored in the memory, corresponding to the long-cycling level.

According to an example embodiment, the method may further comprise: providing information related to battery charging of the electronic device to another electronic device paired with the electronic device through the second external electronic device to set the same long-cycling level as the other electronic device, wherein the information related to battery charging of the electronic device may include the remaining battery capacity, the long-cycling level, the changed full charge voltage value, and the changed recharge voltage value.

According to an example embodiment, changing the set full charge voltage and the set recharge voltage of the battery may include: receiving information related to battery charging of another electronic device formed as a pair with the electronic device from the second external electronic device, and changing the set full charge voltage and the set recharge voltage based on the information related to battery charging of the other electronic device. According to an example embodiment, the information related to battery charging of the other electronic device may include a remaining battery capacity, a long-cycling level, a full charge voltage value, and a recharge voltage value.

According to an example embodiment, the method may further comprise: identifying whether to replace the other device and whether to replace a battery of the other electronic device in response to identifying that the long-cycling level of the other device is changed to a high level like the long-cycling level of the electronic device without a change in the remaining battery capacity of the other electronic device.

According to an example embodiment, changing the set full charge voltage and the set recharge voltage of the battery based on the long-cycling level may include: identifying a long-cycling level having a high value based on the long-cycling level of the electronic device being different from the long-cycling level of the other electronic device, setting the long-cycling level of the electronic device to the long-cycling level having the high value, changing the set full charge voltage and the set recharge voltage to a full charge voltage value and a recharge voltage value stored in the memory, corresponding to the long-cycling level having the high value, and providing the other electronic device with information related to battery charging including the long-cycling level having the high value to set the long-cycling level of the electronic device and the long-cycling level of the other electronic device to be the same.

According to an example embodiment, the long-cycling level may be set to a level that increases as the remaining battery capacity decreases. According to an example embodiment, each of the set full charge voltage and the set recharge voltage may be set to a value that decreases as the long-cycling level increases.

According to an example embodiment, the method may further comprise: receiving product information about another electronic device connected with the second external electronic device using the wireless communication scheme and paired with the electronic device from the second external electronic device, and based on the received product information being identical to product information about the electronic device, transmitting battery charging-related information about the electronic device to change the set full charge voltage and the set recharge voltage like the electronic device.

According to an example embodiment, in a non-transitory storage medium storing a program, the program may include instructions that, when executed by at least one processor, comprising processing circuitry (e.g., the processor 310 of FIG. 3), of an electronic device (e.g., the electronic device 201 of FIGS. 2A, 2C, and 3). individually or collectively, cause the electronic device to: charge a battery (e.g., the battery 321 of FIG. 3) of the electronic device with power applied from a first external electronic device (e.g., the first external electronic device 203 of FIGS. 2A and 2B) based on being connected to the first external electronic device, identify a recharge entry time at which the battery reaches a set recharge voltage after the battery is fully charged, identify a remaining battery capacity based on the recharge entry time, identify a long-cycling level based on the remaining battery capacity, and change a set full charge voltage and the set recharge voltage of the battery based on the long-cycling level.

In conventional sound devices, the battery characteristics are not fully consistent. Despite a short charge-discharge cycle, old products which lack battery capacity correction have the actual battery capacity smaller than the battery capacity set in electronic device and may thus experience a rapid drop to 0% in the low-voltage period (e.g., 20% or less) during use. Thus, either of the batteries may be more quickly discharged rather than both the batteries being evenly discharged. To address the issues with the battery characteristics of the conventional sound devices, the electronic device (e.g., the electronic device 201 of FIGS. 2A and 2C) according to an embodiment may provide a battery use environment in which the left/right batteries are evenly discharged rather than either being more quickly discharged when the user uses the electronic device, thereby preventing and/or reducing the quick discharge issue and enabling efficient battery lifespan management. Other various effects may be provided directly or indirectly in the disclosure.

The various example embodiments disclosed herein are provided for description and to aid in understanding of the disclosed technology and does not limit the scope of the disclosure. Accordingly, the scope of the disclosure should be interpreted as including all changes or various embodiments based on the technical spirit of the disclosure.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device, comprising:
memory storing instructions;
a battery;
a communication circuit; and
at least one processor, comprising processing circuitry,
wherein at least one processor, individually or collectively, is configured to execute the instructions and to cause the electronic device to:
based on the electronic device being connected to a first external electronic device through the communication circuit, charge the battery with power applied from the first electronic device;
identify a recharge entry time at which the battery reaches a set recharge voltage after the battery is fully charged;
based on the recharge entry time, identify a remaining battery capacity;
based on the remaining battery capacity, identify a long-cycling level; and
based on the long-cycling level, change a set full charge voltage and the set recharge voltage of the battery.

2. The electronic device of claim 1, wherein at least one processor, individually or collectively, cause the electronic device to:
repeatedly identify the recharge entry time at which the battery reaches the set recharge voltage after the battery is fully charged, at a charge-discharge cycle during a designated time;
obtain an average time of recharge entry times identified during the designated time; and
identify the average time as the recharge entry time for identifying the remaining battery capacity.

3. The electronic device of claim 1, wherein at least one processor, individually or collectively, is configured to cause the electronic device to change the set full charge voltage and the set recharge voltage of the battery to a full charge voltage value and a recharge voltage value stored in the memory, corresponding to the long-cycling level.

4. The electronic device of claim 1, wherein at least one processor, individually or collectively, is configured to cause the electronic device to: provide information related to battery charging of the electronic device to another electronic device formed as a pair with the electronic device through the first external electronic device to set the same long-cycling level as the other electronic device, and
wherein the information related to battery charging of the electronic device includes the remaining battery capacity, the long-cycling level, the changed full charge voltage value, and/or the changed recharge voltage value.

5. The electronic device of claim 1, wherein at least one processor, individually or collectively, is configured to cause the electronic device to:
receive information related to battery charging of another electronic device paired with the electronic device from a second external electronic device; and
change the set full charge voltage and the set recharge voltage based on the information related to battery charging of the other electronic device, wherein the information related to battery charging of the other electronic device includes a remaining battery capacity, a long-cycling level, a full charge voltage value, and/or a recharge voltage value.

6. The electronic device claim 1, wherein at least one processor, individually or collectively, is configured to cause the electronic device to: identify whether to replace the other electronic device and whether to replace a battery of the other electronic device in response to identifying that the long-cycling level of the other electronic device is changed to a high level like the long-cycling level of the electronic device without a change in the remaining battery capacity of the other electronic device.

7. The electronic device of claim 1, wherein at least one processor, individually or collectively, is configured to cause the electronic device to:
identify a long-cycling level having a high value based on the long-cycling level of the electronic device being different from the long-cycling level of the other electronic device;
set the long-cycling level of the electronic device to the long-cycling level having the high value;
set or change the set full charge voltage and the set recharge voltage to a full charge voltage value and a recharge voltage value stored in the memory, corresponding to the long-cycling level having the high value; and
provide the other electronic device with information related to battery charging including the long-cycling level having the high value to set the long-cycling level of the electronic device and the long-cycling level of the other electronic device to be the same.

8. The electronic device of claim 1, wherein the long-cycling level is set to a level that increases as the remaining battery capacity decreases, and
wherein each of the set full charge voltage and the set recharge voltage is set to a value that decreases as the long-cycling level increases.

9. The electronic device of claim 1, wherein at least one processor, individually or collectively, is configured to cause the electronic device to:
charge the battery with the voltage applied from the first external electronic device based on the electronic device being accommodated in an accommodation space inside a first housing of the first external electronic device, and a second housing of the first external electronic device being in a closed state; and
refrain from performing wireless communication with a second external electronic device based on charging the battery by the first external electronic device.

10. The electronic device of claim 1, wherein at least one processor individually or collectively, is configured to cause the electronic device to:
control the communication circuit to receive product information about another electronic device connected with the second external electronic device using the wireless communication scheme and paired with the electronic device from the second external electronic device; and
based on the received product information being identical to product information about the electronic device, control the communication circuit to transmit battery charging-related information about the electronic device to change the set full charge voltage and the set recharge voltage like the electronic device.

11. A method of operating an electronic device, the method comprising:
based on being connected to the first external electronic device, charging a battery of the electronic device with power applied from a first external electronic device;
identifying a recharge entry time at which the battery reaches a set recharge voltage after the battery is fully charged;
based on the recharge entry time, identifying a remaining battery capacity;
based on the remaining battery capacity, identifying a long-cycling level; and
based on the long-cycling level, changing a set full charge voltage and the set recharge voltage of the battery.

12. The method of claim 11, wherein identifying the recharge entry time includes:
repeatedly identifying the recharge entry time at which the battery reaches the set recharge voltage after the battery is fully charged, at a charge-discharge cycle during a designated time;
obtaining an average time of recharge entry times identified during the designated time; and
identifying the average time as the recharge entry time for identifying the remaining battery capacity.

13. The method of claim 11, wherein changing the set full charge voltage and the set recharge voltage of the battery includes:
changing the set full charge voltage and the set recharge voltage of the battery to a full charge voltage value and a recharge voltage value stored in the memory, corresponding to the long-cycling level.

14. The method of claim 11, further comprising:
providing information related to battery charging of the electronic device to another electronic device formed as a pair with the electronic device through the first external electronic device to set the same long-cycling level as the other electronic device, and
wherein the information related to battery charging of the electronic device includes the remaining battery capacity, the long-cycling level, the changed full charge voltage value, and/or the changed recharge voltage value.

15. The method of claim 11, wherein changing the set full charge voltage and the set recharge voltage of the battery includes:
receiving information related to battery charging of another electronic device paired with the electronic device from the second external electronic device; and
changing the set full charge voltage and the set recharge voltage based on the information related to battery charging of the other electronic device, and
wherein the information related to battery charging of the other electronic device includes a remaining battery capacity, a long-cycling level, a full charge voltage value, and/or a recharge voltage value.

16. The method of claim 11, further comprising:
identifying whether to replace the other device and whether to replace a battery of the other electronic device in response to identifying that the long-cycling level of the other device is changed to a high level like the long-cycling level of the electronic device without a change in the remaining battery capacity of the other electronic device.

17. The method of claim 11, wherein changing the set full charge voltage and the set recharge voltage of the battery based on the long-cycling level includes:
identifying a long-cycling level having a high value based on the long-cycling level of the electronic device being different from the long-cycling level of the other electronic device;
setting the long-cycling level of the electronic device to the long-cycling level having the high value;
changing the set full charge voltage and the set recharge voltage to a full charge voltage value and a recharge voltage value stored in the memory, corresponding to the long-cycling level having the high value; and
providing the other electronic device with information related to battery charging including the long-cycling level having the high value to set the long-cycling level of the electronic device and the long-cycling level of the other electronic device to be the same.

18. The method of claim 11, wherein the long-cycling level is set to a level that increases as the remaining battery capacity decreases, and
wherein each of the set full charge voltage and the set recharge voltage is set to a value that decreases as the long-cycling level increases.

19. The method of claim 11, further comprising:
receiving product information about another electronic device connected with the second external electronic device using the wireless communication scheme and paired with the electronic device from the second external electronic device; and
based on the received product information being identical to product information about the electronic device, transmitting battery charging-related information about the electronic device to change the set full charge voltage and the set recharge voltage like the electronic device.

20. A non-transitory computer-readable storage medium storing a program including instructions that, when executed by at least one processor, comprising processing circuitry, of an electronic device individually or collectively, cause the electronic device to:
based on being connected to a first external electronic device, charge a battery of the electronic device with power applied from the first external electronic device;
identify a recharge entry time at which the battery reaches a set recharge voltage after the battery is fully charged;
based on the recharge entry time, identify a remaining battery capacity;
based on the remaining battery capacity, identify a long-cycling level; and
based on the long-cycling level, change a set full charge voltage and the set recharge voltage of the battery.
